(19) United States
(12) Patent Application Publication
(10) Pub. No.: US 2025/0379052 A1
(43) Pub. Date: Dec. 11, 2025

(54) AMORPHOUS MULTI-METAL-DOPED FILM FOR HARDMASK APPLICATION

(71) Applicant: Applied Materials, Inc., Santa Clara, CA (US)

(72) Inventors: Guangyan ZHONG, Sunnyvale, CA (US); Baorui CHENG, Santa Clara, CA (US); Kashish SHARMA, Santa Clara, CA (US); Aykut AYDIN, Sunnyvale, CA (US); Rui CHENG, Santa Clara, CA (US); Ping-Hwa HSIEH, Santa Clara, CA (US); Kelvin CHAN, San Ramon, CA (US); Sahmuganathan VICKNESH, Singapore (SG); Tien Fak TAN, Campbell, CA (US); Ganesh BALASUBRAMANIAN, Fremont, CA (US); Xinhai HAN, Santa Clara, CA (US); Abhijit Basu MALLICK, Fremont, CA (US); Han WANG, Palo Alto, CA (US); Sze Chieh TAN, Singapore (SG); Karthik JANAKIRAMAN, San Jose, CA (US); Andrea Leoncini, Singapore (SG); Jungmin KO, San Jose, CA (US); Tom S CHOI, San Jose, CA (US)

(21) Appl. No.: 18/734,417

(22) Filed: Jun. 5, 2024

(51) Int. Cl. H01L 21/033

(52) U.S. Cl. CPC H01L 21/0337; H01L 21/0332

(57) ABSTRACT

Implementations of the present disclosure generally relate to the fabrication of integrated circuits. More particularly, the implementations described herein provide techniques for deposition of hardmask films on a substrate. In one embodiment, a method of forming a multi-metal hardmask film on a substrate disposed in a processing chamber, including flowing at least one pretreatment gas into the processing chamber; and flowing a main deposition gas mixture into the processing chamber to form the multi-metal hardmask film, wherein the multi-metal hardmask film comprises a plurality of metals.

### BACKGROUND

### Field

Embodiments of the present disclosure generally relate to the fabrication of integrated circuits. More particularly, the implementations described herein provide techniques for the deposition of hardmask films on a substrate.

### Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is key to VLSI and ULSI success and to the continued effort to increase circuit density and quality of individual substrates and die.

Furthermore, the demands for greater integrated circuit densities also impose demands on the process sequences used in the manufacture of integrated circuit components. For example, in process sequences that use conventional photolithographic techniques, a layer of energy sensitive resist is formed over a stack of material layers disposed on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer. Thus, a highly selective etchant enhances accurate pattern transfer.

As the geometry limits of the structures used to form semiconductor devices are pushed against technology limits, the need for accurate pattern transfer for the manufacture of structures having small critical dimensions and high aspect ratios and structures with different materials has become increasingly difficult to satisfy. For example, the thickness of the energy sensitive resist has been reduced in order to control pattern resolution. Such thin resist layers (e.g., less than about 2000 Å) can be insufficient to mask underlying material layers during the pattern transfer process due to attack by the chemical etchant. An intermediate layer, called a hardmask (“HM”) layer, is often used between the energy sensitive resist layer and the underlying material layers to facilitate pattern transfer because of its greater resistance to chemical etchants.

During etching, the hardmask layer utilized to transfer patterns to the materials is exposed to aggressive etchants for a significant period. After a long period of exposure to the aggressive etchants, the hardmask layer without sufficient etching resistance may be dimensionally changed, resulting in inaccurate pattern transfer and loss of dimensional control. Furthermore, the similarity of the materials selected for the hardmask layer and the adjacent layers disposed in the film stack may result in similar etch properties therebetween, thus resulting in poor selectivity during etching. Poor selectivity between the hardmask layer and adjacent layers may result in non-uniform, tapered, and deformed profile of the hardmask layer, thus leading to poor pattern transfer and failure of accurate structure dimension control.

Thus, there is a need for improved hardmask films with high etch selectivity, low grain size, high modulus, and low roughness (smooth morphology).

### SUMMARY

Implementations of the present disclosure generally relate to the fabrication of integrated circuits. More particularly, the implementations described herein provide techniques for deposition of hardmask films on a substrate. In one embodiment, a method of forming a multi-metal hardmask film on a substrate disposed in a processing chamber, including flowing at least one pretreatment gas into the processing chamber; and flowing a main deposition gas mixture into the processing chamber to form the multi-metal hardmask film, wherein the multi-metal hardmask film comprises a plurality of metals.

In another embodiment, a multi-metal hardmask film on a substrate disposed in a processing chamber, including flowing at least one pretreatment gas into the processing chamber, wherein the pretreatment gas comprises one or more of a hydrogen containing gas and a nitrogen containing gas; flowing a main deposition gas mixture into the processing chamber to form the multi-metal hardmask film, wherein the multi-metal hardmask film comprises a plurality of metals; and supplying a radiofrequency (RF) power while flowing the at least one pretreatment gas and while forming the multi-metal hardmask film.

In yet another embodiment, a layer disposed on a substrate, including two or more metals selected from: tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr); and at least one non-metal comprising one or more of carbon (C), boron (B), nitrogen (N), and silicon (Si), wherein the layer is formed on a dielectric material of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a schematic cross-sectional view of an exemplary processing chamber, according to one or more embodiments of the present disclosure.

FIG. 2 shows a flowchart for an exemplary operation in a deposition method, according to one or embodiments of the present disclosure.

FIG. 3 depicts a film morphology-metal concentration versus grain size relationship of a multi-metal-incorporated carbon film, in accordance with one or more embodiments.

FIG. 4 depicts atomic percentage profiles of various multi-metal hardmask films demonstrating atomic percentage versus etch time, in accordance with one or more embodiments.

FIG. 5A is a plot depicting the etch selectivity of various multi-metal hardmask films, in accordance with one or more embodiments.

FIG. 5B is a plot depicting the grain size of various multi-metal hardmask films, in accordance with one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

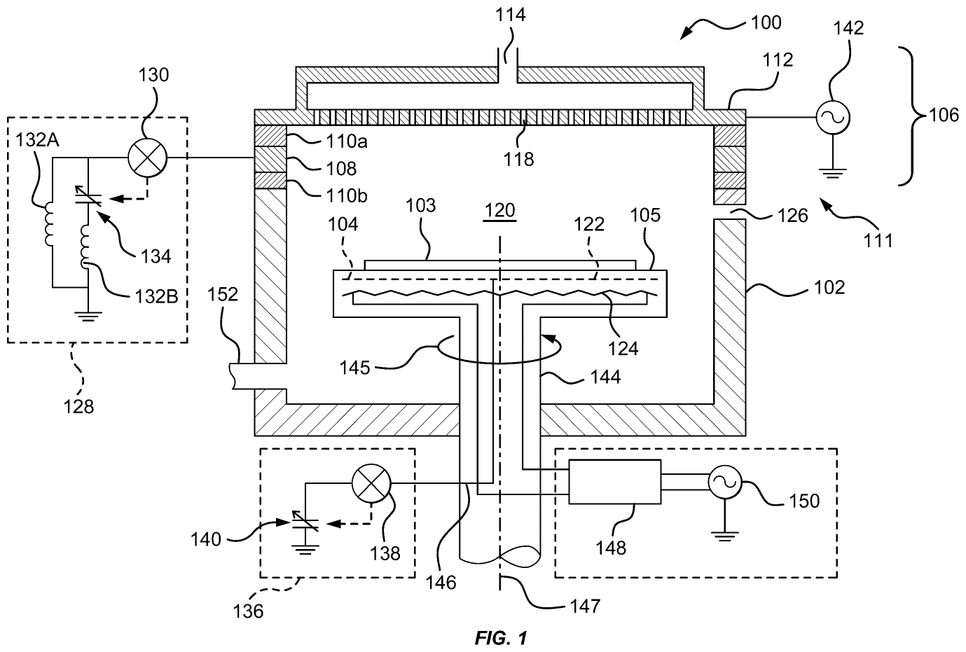

The following disclosure describes techniques for deposition of hardmask films on a substrate. Certain details are set forth in the following description and in FIGS. 1-5 to provide a thorough understanding of various implementations of the disclosure.

Other details describing well-known structures and systems often associated with plasma processing, hardmask film deposition, and etching are not set forth in the following disclosure to avoid unnecessarily obscuring the description of the various implementations.

With the shrinking of feature sizes for logic and memory devices, thinner but stronger hardmask films are required when patterning smaller critical dimension (CD) and high aspect ratio structures. While some metal-doped films (e.g., silicide, boride, and carbide) are promising candidates for hardmask application in logic and memory device fabrication due to their high etch selectivity and high modulus, additional etch selectivity, modulus, and metal concentration (usually >50%) are needed. However, increasing metal concentration in film by doping metal elements at high concentrations results in grain growth and, in turn, columnar and granular morphology. Moreover, the transition from an amorphous film to a crystalline (e.g., a nano-crystalline) film leads to challenges in the patterning process, for example, failed CD uniformity and straight etch profile.

By doping the film with multiple metals (e.g., at a high level at the same time), the tradeoff between etch selectivity and morphology is limited. The impact may be caused by several mechanisms, such as amorphization by alloy formation, amorphization due to atomic size mismatch, and amorphization due to crystal structure disruption. For example, the doping of multiple metals may lead to the formation of certain bonds and/or alloys which are known to exhibit amorphous structures. As another example, doping with multiple metals having different atomic sizes will induce strain and defects into the lattice, and thus cause the film to be more susceptible to amorphization. As yet another example, the high level of extra metal dopant will disrupt the crystalline structure, leading to an amorphous film.

However, high etch selectivity may be achieved by having a high metal concentration in the hardmask film. Low grain size and smooth morphology is achieved by having multiple metal elements combined with non-metal elements at certain, various compositions in the hardmask film. Film adhesion may be achieved by certain plasma treatments prior to deposition of the hardmask film. Further, stress tuning may be achieved by using low frequency radiofrequency bombardment or adjusting the composition. Thus, an amorphous multi-metal-doped hardmask film with a tunable composition and a method of fabricating such film from multiple precursors using chemical vapor deposition (CVD) and/or plasma-enhanced chemical vapor deposition (PECVD) provides for a hardmask film with high etch selectivity and low roughness. In some embodiments, the hardmask material is amorphous or nano-crystalline and exhibits improved etch selectivity while avoiding a large grain size/morphology and the high-stress issues associated with other metallic hardmask films. At the same time, the film interface (e.g., a surface of the substrate) can be tuned to provide improved adhesion over various substrates that are used for hardmask fabrication and patterning. The film stress can also be tuned to the desired range by use of low frequency radiofrequency bombardment without adversely impacting other critical properties such as adhesion and grain size.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

Implementations described herein will be described below in reference to a PECVD process that can be carried out using any suitable thin film deposition system. Examples of suitable systems include the CENTURA® systems which may use a DXZ® processing chamber, PRECISION 5000® systems, PRODUCER® systems, PRODUCER® GT™ systems, PRODUCER® XP PRECISION™ systems, PRODUCER® SE™ systems, and TESSERACT® systems, which are commercially available from Applied Materials, Inc., of Santa Clara, Calif. Other tools capable of performing PECVD processes may also be adapted to benefit from the implementations described herein. In addition, any system enabling the PECVD processes described herein can be used to advantage. The apparatus description described herein is illustrative and should not be construed or interpreted as limiting the scope of the implementations described herein.

FIG. 1 shows a cross-sectional view of an exemplary processing chamber 100 according to some embodiments of the present technology. FIG. 1 provides an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

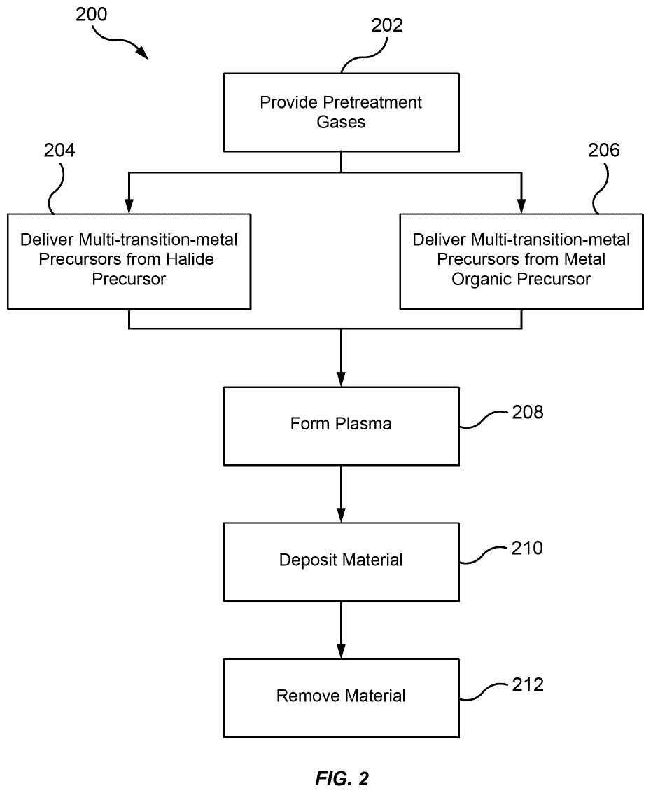

FIG. 2 shows a flowchart for exemplary operations in a deposition method 200, according to one or embodiments of the present disclosure. The deposition method 200 may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated.

Method 200 may include additional operations prior to initiation of the listed operations. For example, additional processing operations may include forming structures on a semiconductor substrate, including stacks of material for 3D NAND, forming transistor or other memory structures, or any other processing that may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be disposed on a substrate support, which may be a pedestal, such as substrate support 104, and which may reside in a processing region of the chamber, such as processing volume 120 described above.

The substrate may be or include any number of materials on which materials may be disposed. The substrate may be or include silicon, germanium, dielectric materials including silicon oxide or silicon nitride, metal materials, or any number of combinations of these materials, which may be the substrate, or materials formed on the substrate.

Method 200 starts at operation 202. At operation 202, pretreatment of underlayer (e.g., the surface of the substrate) is performed to prepare the surface of the substrate for deposition. For example, a pretreatment can be performed to provide certain ligand terminations on the surface of the substrate, which may facilitate nucleation of a film to be disposed. For example, hydrogen, oxygen, carbon, nitrogen, or other molecular terminations, including any combination of these atoms or radicals may be adsorbed, reacted, or formed on a surface of a substrate. Additionally, material removal may be performed, such as reduction of native oxides or etching of material, or any other operation that may prepare one or more exposed surfaces of the substrate for deposition. In some embodiments, the underlayer is treated by flowing pretreatment gases into the processing volume (e.g., processing volume 120 of FIG. 1). In some embodiments, the pretreatment gases are a hydrogen containing gas and/or a nitrogen containing gas. In some embodiments, the hydrogen containing gas is H₂. In some embodiments, the nitrogen containing gas is N₂. In some embodiments, the hydrogen containing gas is flowed into the processing volume at a flow rate of between 20 standard cubic centimeter per minute (sccm) to 2000 sccm, such as 1000 sccm. In some embodiments, the nitrogen containing gas is flowed into the processing volume at a flow rate of between 100 sccm to 10000 sccm, such as 2000 sccm. In some embodiments, the underlayer is treated at a radiofrequency (RF) between about 13 MHz, such as 13.56 MHz, and about 27 MHz, such as 27.12 MHz, at a power between 300 Watts (W) to 3000 W, such as 700 W. In some embodiments, the underlayer is exposed to the pretreatment gases for a predetermined amount of time between about 15 seconds and about 60 seconds, at a flow rate between about 500 sccm and 2000 sccm.

At operations 204 and 206, a multi-metal-incorporated carbon film (e.g., multi-transition-metal-incorporated carbon film) is formed. In various embodiments, the multi-metal-containing precursor may be delivered to the processing region of the processing chamber with either a halide precursor (at operation 204) or with a metal-organic precursor (at operation 206). In some embodiments, during the deposition or formation of the multi-metal-incorporated carbon film, the temperature of the processing chamber is maintained between a range of about 100° C. to about 800° C., such as about 600° C. In some embodiments, during the deposition or formation of the multi-metal-incorporated carbon film, the pressure of the processing chamber is maintained between a range of about 0.1 Torr to about 100 Torr, such as 2.5 Torr. Plasma enhanced chemical vapor deposition (PECVD) may be performed in some embodiments of the present disclosure, which may facilitate material reactions and deposition.

As noted above, some embodiments of the present disclosure may encompass formation or deposition of multi-metal and carbon materials, which may be characterized conventionally by increased surface roughness, such as in comparison to thermally or plasma produced silicon and carbon films, for example. By controlling formation characteristics and precursors utilized in the processing, the present disclosure may produce metal-containing films characterized by reduced surface roughness and grain size, while also producing materials that may be more easily removed subsequent processing.

In some embodiments, the multi-metal containing precursor comprises a plurality of metal containing precursors. In some embodiments, the plurality of metal containing precursors contain a transition metal. In some embodiments, the plurality of metal containing precursors may contain one or more of: tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and/or zirconium (Zr). In some embodiments, the metal containing precursors may be delivered either by vapor draw or by using a bubbler, including with heating and without heating. In some embodiments, the multi-metal containing precursor may be diluted using a carrier gas, such as argon (Ar) or helium (He), with the flow controlled using a mass flow controller (MFC) and/or a liquid flow meter (LFM). In some embodiments, the halide precursor may contain one or more of: fluorine (F), chlorine (Cl), bromine (Br), and/or iodine (I). In some embodiments, at operations 204, 206, other precursors may be flowed into the processing chamber, such as: hydrogen (e.g., H₂), argon (Ar), carbon (e.g., C₃H₆ or C₂H₂), boron (e.g., B₂H₆), nitrogen (e.g., N₂ or NH₃), and/or silicon (e.g., SiH₄). In some embodiments, the metal-organic precursor may contain one or more of: tetrakis(dimethylamido)titanium, tetraisopropoxytitanium, Dimethylbis(tbutylcyclopentadienyl)titanium, tetrakis(neopentyl)titanium, Dimethylbis(methylcyclopentadienyl)zirconium, tetrakis(dimethylamido)zirconium, Dimethylbis(methylcyclopentadienyl)hafnium, tetrakis(dimethylamido)hafnium, (t-butylimido)tris(diethylamino)niobium, pentaethoxyniobium, (t-butylimido)tris(diethylamino)tantalum, pentakis(dimethylamido)tantalum, pentaethoxytantalum, bis(ethylbenzene)molybdenum, molybdenum hexacarbonyl, bis(isopropylcyclopentadienyl)molybdenum dihydride, (Ethylcyclopentadienyl)(dicarbonyl)nitrosomolybdenum, tungsten hexacarbonyl, bis(isopropylcyclopentadienyl)tungsten dihydride, (ethylcyclopentadienyl)tricarbonyltungsten hydride, tris(3-hexyne)carbonyltungsten, diethylzinc, (ethylcyclopentadienyl)isopreneruthenium, bis(ethylcyclopentadienyl)ruthenium, (ethylbenzene)(cyclohexadienyl)ruthenium, (Methylcyclopentadienyl)trimethylplatinum, (ethylcyclopentadienyl)(cyclohexadienyl)iridium, (ethylcyclopentadienyl)(cyclooctadienyl)iridium, bis(ethylcyclopentadienyl)cobalt, and cyclopentadienyldicarbonylcobalt.

The precursors delivered may all be used to form a plasma within the processing region of the semiconductor processing chamber at operation 208. At operation 210, a multi-metal-and-carbon material may be disposed on the substrate. One or more additional precursors may also be included, such as argon, helium, nitrogen, or other carrier or inert gases, which may facilitate plasma formation and development of film characteristics. By producing plasma effluents of the precursors according to some embodiments of the present technology, material roughness and grain formation may be controlled and limited.

For example, incorporating multiple metal materials in the film may cause more expansive grain formation instead of producing a more amorphous film. By incorporating an additional hydrogen and or inert source, such as argon or helium, along with controlling environment and plasma parameters, a film modification, or profile etch, may be performed simultaneously with the deposition of material. For example, through reaction and/or physical interaction with features being formed of the multi-metal-and-carbon material, hydrogen or inert gas ions and/or neutral species may trim the grain and surface formation while a more uniform profile of formation is being produced. Consequently, grain formation may be lower than in conventional processes attempting to incorporate multiple metals. To provide sufficient radicals to the process, the hydrogen-containing precursor and/or inert gas or carrier gas may be provided at a greater flow rate than the multi-metal-containing precursor.

Any number of precursors may be used with the present disclosure with regard to the multi-metal-containing precursor, the hydrogen-containing precursor, and the carbon-containing precursor, when included. Any number of transition metals may be encompassed by the present technology, including cobalt, chromium, hafnium, molybdenum, osmium, rhenium, ruthenium, tantalum, titanium, tungsten, zirconium, or any other metal or transition metal that may be provided as a deposition precursor. For example, the transition-metal precursors may be or include transition-metal halides, as well as organometallic precursors. When organometallic precursors are used, a carbon-containing precursor may not be used, for example. As one non-limiting example, the transition metal may be or include ruthenium or osmium. Exemplary precursors may be or include bis(cyclopentadienyl)ruthenium, bis(ethylcyclopentadienyl)ruthenium, triruthenium dodecacarbonyl, triosmium dodecacarbonyl, or any other ruthenium or osmium precursor, including halogen-containing precursors, as well as any other transition-metal precursor.

Hydrogen-containing precursors may include diatomic hydrogen, as well as hydrogen-containing materials, such as may be or include carbon-containing precursors. When they are included, carbon-containing precursors may be or include any hydrocarbon, or any material including or consisting of carbon and hydrogen. In some embodiments, the carbon-containing precursor may be characterized by one or more carbon-carbon double bonds and/or one or more carbon-carbon triple bonds. Accordingly, in some embodiments the carbon-containing precursor may be or include an alkene or an alkyne, such as acetylene, ethylene, propene, or any other carbon-containing material. The precursor may include carbon-and-hydrogen-containing precursors, which may include any amount of carbon and hydrogen bonding, along with any other element bonding, although in some embodiments the carbon-containing precursor may consist of carbon-to-carbon and carbon-to-hydrogen bonding.

The incorporation of the transition metal and or the carbon may be tuned to increase or decrease the incorporation based on one or more deposition parameters discussed further below. In some embodiments, the transition metal may be incorporated at greater than or about 5 at. %, and may be incorporated at greater than or about 10 at. %, greater than or about 15 at. %, greater than or about 20 at. %, greater than or about 25 at. %, greater than or about 30 at. %, greater than or about 35 at. %, greater than or about 40 at. %, greater than or about 45 at. %, greater than or about 50 at. %, greater than or about 55 at. %, greater than or about 60 at. %, greater than or about 65 at. %, greater than or about 70 at. %, or higher, although as the transition-metal incorporation increases, surface roughness may increase, and roughness characteristics may exceed thresholds discussed above due to formation of a more columnar structure. Accordingly, in some embodiments the transition metal may be incorporated at less than or about 75 at. %, and may be maintained at less than or about 70 at. %, less than or about 65 at. %, less than or about 60 at. %, less than or about 55 at. %, less than or about 50 at. %, or less, which may maintain a majority carbon concentration in some embodiments. Carbon, hydrogen, and/or additional transition metals may represent the remainder percentage in any compositions including transition metal incorporation within the ranges noted above, along with an amount of nitrogen, oxygen, or other residual materials that may be incorporated in trace amounts.

One or more additional aspects of the deposition may also be tuned to improve aspects of the deposition being performed. For example, the plasma power may impact the extent of precursor dissociation, and embodiments may include both high-frequency RF and low-frequency RF applied to the electrodes. An interface layer may be produced in some embodiments to facilitate adhesion of the materials formed. During generation of the plasma, an initial power may be applied by the high-frequency RF source, such as to a faceplate or first electrode, which may be subsequently ramped or stepped to a bulk deposition power. In some embodiments, the high-frequency RF source may be maintained between about 300 W to about 3000 W, such as 700 W. By utilizing a lower generation power, a lower amount of dissociation may occur, which may increase carbon incorporation in the film. At the substrate interface, this may also facilitate production of smaller grain sizes throughout the film disposed. In some embodiments, the grain size is less than about 35 Å, such as less than 33 Å. Accordingly, in some embodiments the plasma may initially be generated at a high-frequency plasma power, such as operating at 13.56 MHz or 27 MHz, among other frequencies, at a power of less than or about 3000 W, and may be generated at a power of less than or about 2000 W, less than or about 1000 W, such as 700 W.

Subsequent a first period of time, the power may be ramped or stepped to a higher power, which may increase deposition as well as transition metal incorporation. For example, the power may be stepped or ramped to a power greater than or about 500 W, and may be stepped or ramped to a power greater than or about 600 W, greater than or about 700 W, greater than or about 800 W, greater than or about 900 W, greater than or about 1000 W, greater than or about 1100 W, greater than or about 1200 W, greater than or about 1300 W, greater than or about 1400 W, greater than or about 1500 W, or higher.

A low-frequency RF power may also be applied, such as to the substrate, pedestal, or a second electrode, and which may be applied at less than or about 1000 kHz, and may be applied at less than or about 750 kHz, less than or about 500 kHz, less than or about 450 kHz, less than or about 400 kHz, less than or about 350 kHz, less than or about 300 kHz, less than or about 250 kHz, less than or about 200 kHz, or less, including down to zero, where the low-frequency power may not be used. The low-frequency RF supply may increase ion energy, and physical impact on the film being produced, which may facilitate reduction in grain size as discussed above. Additionally, the power may provide lower film stress. For example, while carbon hardmasks may be characterized by a more neutral film, metal-containing materials may be characterized by a more tensile stress, which may cause stress on the underlying structure, especially subsequent mask patterning. By increasing a low-frequency RF power, the stress may be lowered to produce a film characterized by a more neutral stress, similar to a carbon hardmask. Accordingly, in some embodiments the low-frequency power may be applied at greater than or about 100 W, and may be applied at greater than or about 150 W, greater than or about 200 W, greater than or about 250 W, greater than or about 300 W, greater than or about 350 W, greater than or about 400 W, greater than or about 450 W, greater than or about 500 W, or more, although in some embodiments the power may be maintained at less than or about 500 W, which may cause roughness to increase due to increased bombardment.

The temperatures of the substrate may additionally impact the deposition. For example, in some embodiments the substrate may be maintained at a temperature of greater than or about 300° C., and may be maintained at a temperature of greater than or about 320° C., greater than or about 340° C., greater than or about 360° C., greater than or about 380° C., greater than or about 400° C., greater than or about 420° C., greater than or about 440° C., greater than or about 460° C., greater than or about 480° C., greater than or about 500° C., or greater. Additionally, the pressure within the processing region may affect the amount of ionization and physical interaction performed during the deposition. By lowering a processing pressure, lower ionization may occur, which may increase carbon concentration, such as at an interfacial region. By increasing a processing pressure, increased ionization may occur, which may facilitate increasing transition metal incorporation and deposition rate. Hence, similar to plasma power, pressure within the processing region may be adjusted from a first pressure during generation of the plasma to a second, higher pressure after a first period of time. Accordingly, in some embodiments a processing pressure during generation may be maintained at less than or about 6 Torr, and may be maintained at less than or about 5 Torr, less than or about 4 Torr, less than or about 3 Torr, less than or about 2 Torr, or less. Subsequent the first period of time, the pressure may be stepped or ramped to greater than or about 5 Torr, greater than or about 6 Torr, greater than or about 7 Torr, greater than or about 8 Torr, greater than or about 9 Torr, greater than or about 10 Torr, greater than or about 11 Torr, greater than or about 12 Torr, greater than or about 13 Torr, greater than or about 14 Torr, greater than or about 15 Torr, or more, in some embodiments.

As noted previously, process conditions may be initially set to facilitate adhesion and grain control, followed by adjustments for bulk deposition after a first period of time. Because the interface layer may be limited to a few monolayers to promote adhesion, the first period of time may be maintained at less than or about 10 seconds, and may be maintained at less than or about 9 seconds, less than or about 8 seconds, less than or about 7 seconds, less than or about 6 seconds, less than or about 5 seconds, less than or about 4 seconds, less than or about 3 seconds, less than or about 2 seconds, or less, followed by a transition to bulk deposition. In some embodiments, multiple subsequent periods of time may be implemented in loop, followed by adjustments for bulk deposition. As an additional operation that may be performed during the first period of time, a boron-containing precursor and/or a nitrogen-containing precursor may be included with the transition-metal precursor, which may increase adhesion and interfacial properties. Delivery of the boron-containing precursor or the nitrogen-containing precursor, which may include diborane or any other boron-containing precursor as well as diatomic nitrogen or any other nitrogen-containing precursor, may be halted after the first period of time. By performing deposition according to embodiments of the present technology, reduced roughness of transition-metal-and-carbon-containing films may be afforded, which may improve hardmask effectiveness.

Additionally, in some embodiments of the present technology, mask removal subsequent processing may be performed by ashing. For example, after mask deposition, any number of operations may be performed including photolithography and mask opening, as well any number of patterning or etching operations utilizing the mask. After the processing has been completed, the mask may be removed or etched away at optional operation 212. While conventional technologies may be forced to utilize more aggressive etching processes when metals are incorporated in the films, the present technology may utilize transition metals that may ash in an oxygen-containing plasma or with ozone. Although any number of wet etching or dry etching, such as utilizing plasma-enhanced halides, may be used in some embodiments, by utilizing transition metals that may produce volatile oxygen-containing materials, the present technology may allow stripping or ashing similar to carbon hardmasks.

However, as temperature increases, alternative oxide materials may be produced or additional phases of the metal may be produced, which may be characterized by reduced volatility, and may limit or prevent removal by oxygen or other etchants. Accordingly, to ensure the production of volatile oxides, in some embodiments the removal may be performed at a temperature of less than or about 500° C., and may be performed at a temperature of less than or about 450° C., less than or about 400° C., less than or about 380° C., less than or about 360° C., less than or about 340° C., less than or about 320° C., less than or about 300° C., less than or about 280° C., or less. Accordingly, by depositing and/or removing mask materials according to embodiments of the present technology, hardmasks including transition metals may be formed, which may be characterized by reduced roughness and stress, while being characterized by improved removal and deposition compared to conventional technologies.

### EXAMPLES

The following non-limiting examples are provided to further illustrate implementations described herein. However, the examples are not intended to be all-inclusive and are not intended to limit the scope of the implementations described herein. In one example, a tungsten molybdenum carbide hardmask film was fabricated by using WF₆+MoF₆+C₃H₆+H₂ at 480° C. and 700 W RF (13.56 MHz) power in a PECVD reactor with Ar and He as diluting gases. Prior to the film deposition, the underlayer (e.g. a substrate) is treated by flowing H₂ at a flow rate range between about 20 sccm to about 2000 sccm (e.g. 1000 sccm), and N₂ at a flow rate range between about 100 sccm to about 10000 sccm (e.g. 2000 sccm) with a 700 Watt high frequency radiofrequency (HFRF) to help with film adhesion to the surface of the substrate. The treatment of the underlayer is followed by the film deposition, where MoFE is flowed at a flow rate of 100 mgm, vaporized at IV, WFE at a flow rate of 10 sccm, and C₃H₆ at a flow rate of 50 sccm. The HFRF is maintained at a range between about 300 W to about 3000 W (e.g. 700 W), while Ar is flowed at a flow rate range between about 1000 sccm and about 8000 sccm (e.g. 4000 sccm) which serves as a dilution gas; and H₂ is flowed at a flow rate range between about 1000 sccm to 20000 sccm (e.g. 3000 sccm) which prevents existence of any fluorine residue on the hardmask film.

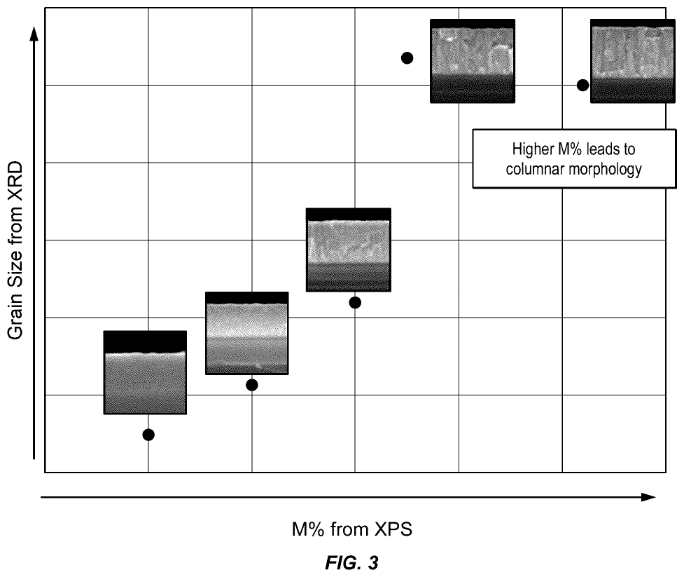

FIG. 3 depicts a film morphology-metal concentration relationship, in accordance with one or more embodiments. The film morphology-metal concentration relationship with corresponding scanning electron micrograph (SEM) photos demonstrates the roughness (e.g., grain size from x-ray diffraction (XRD)) in relation to the percent of metal concentration (from x-ray photoelectron spectra (XPS)). In some embodiments, a higher percentage of metal concentration leads to increased grain size (e.g., columnar morphology).

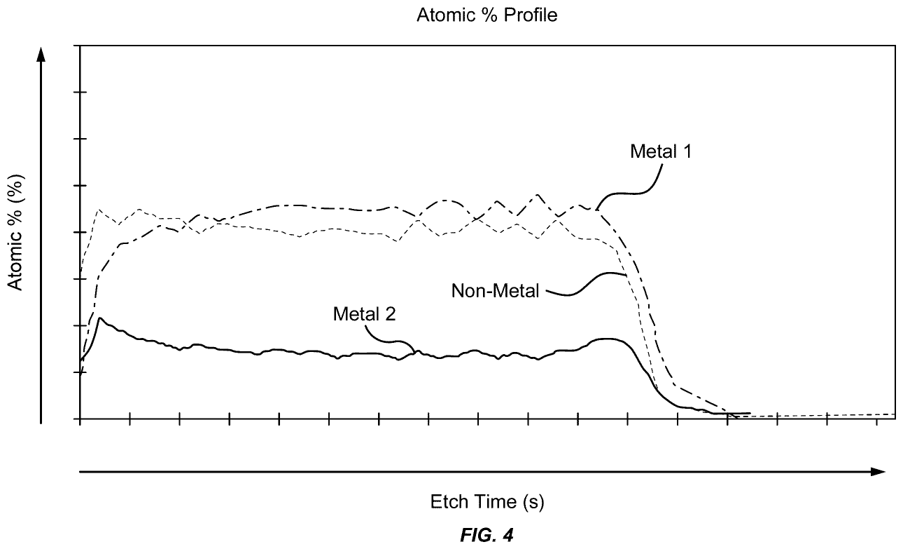

FIG. 4 depicts atomic percentage profiles demonstrating atomic percentage as a function of etch time relationship of various multi-metal hardmask films formed according to implementations described herein. Metal 1 is a first metal in a bi-metal doped hardmask film (e.g., tungsten), metal 2 is a second metal in the bi-metal doped hardmask film (e.g., molybdenum), and Non-Metal is a non-metal in the bi-metal doped hardmark film (e.g., carbide).

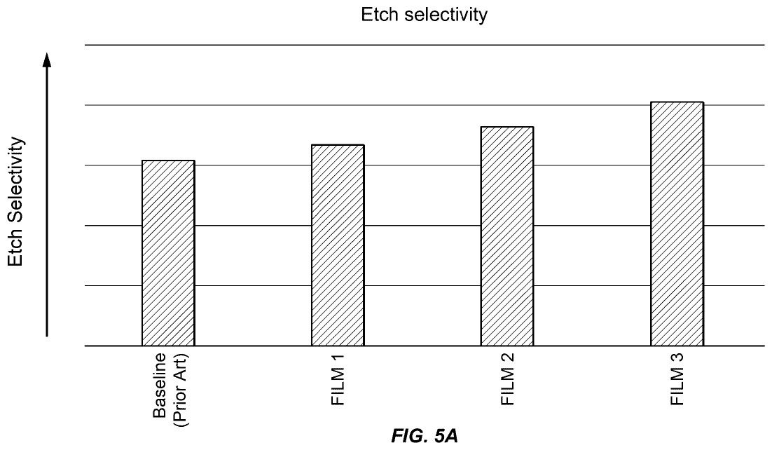

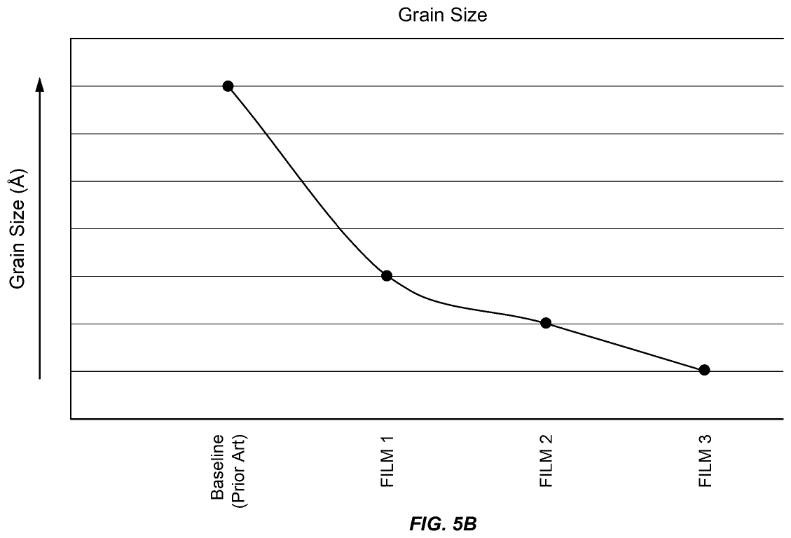

FIG. 5A is a plot demonstrating the etch selectivity of various multi-metal hardmask films formed according to implementations described herein with the etch selectivity of a baseline hardmask film (e.g., a hardmask film having a single metal doped film). FILMS 1, 2, and 3 may be a multi-metal hardmask films (e.g., tungsten molybdenum carbide) formed according to implementations described herein, where FILM 1 has a greater concentration of bi-metal doping than FILM 2, and FILM 2 has a greater concentration of bi-metal doping than FILM 3.

FIG. 5B is a plot demonstrating the grain size of various multi-metal hardmask films formed according to implementations described herein, including the grain size (A) of a baseline hardmask film (e.g., a hardmask film having a single metal doped film). FILMS 1, 2, and 3 may be multi-metal hardmask films (e.g., tungsten molybdenum carbide) formed according to implementations described herein, where FILM 1 has a greater concentration of bi-metal doping than FILM 2, and FILM 2 has a greater concentration of bi-metal doping than FILM 3.

In one embodiment, a method of forming a multi-metal hardmask film on a substrate disposed in a processing chamber, including flowing at least one pretreatment gas into the processing chamber; and flowing a main deposition gas mixture into the processing chamber to form the multi-metal hardmask film, wherein the multi-metal hardmask film comprises a plurality of metals. The at least one pretreatment gas comprises one or more of a hydrogen containing gas and a nitrogen containing gas. The multi-metal hardmask film further comprises at least one non-metal. The at least one non-metal comprises one or more of carbon (C), boron (B), nitrogen (N), and silicon (Si). The plurality of metals comprise transition metals. The transition metals are selected from: tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr). The main deposition gas mixture comprises a plurality of metal containing precursors. The main deposition gas mixture further comprises at least one non-metal containing precursor, the at least one non-metal containing precursor comprising one or more of carbon (C), boron (B), nitrogen (N), and silicon (Si). At least one metal containing precursor of the plurality of metal containing precursors includes a halide precursor. At least one metal containing precursor of the plurality of metal containing precursors includes a metal-organic precursor. Diluting the main deposition gas mixture using at least one carrier gas. The at least one carrier gas comprises one or more of argon (Ar) and/or helium (He).

In another embodiment, a multi-metal hardmask film on a substrate disposed in a processing chamber, including flowing at least one pretreatment gas into the processing chamber, wherein the pretreatment gas comprises one or more of a hydrogen containing gas and a nitrogen containing gas; flowing a main deposition gas mixture into the processing chamber to form the multi-metal hardmask film, wherein the multi-metal hardmask film comprises a plurality of metals; and supplying a radiofrequency (RF) power while flowing the at least one pretreatment gas and while forming the multi-metal hardmask film. The RF power comprises a high frequency RF power between 300 Watts and 3000 Watts. The plurality of metals comprises two or more of tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr). The at least one non-metal containing precursor comprises one or more of carbon (C), boron (B), nitrogen (N), and silicon (Si). A temperature of the processing chamber is between 25° C. and 600° C. when forming the multi-metal hardmask film on the substrate. A pressure within the processing chamber is between 0.1 Torr and 100 Torr when forming the multi-metal hardmask film on the substrate.

In yet another embodiment, a hardmask layer disposed on a substrate, including two or more metals selected from: tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr); and at least one non-metal comprising one or more of carbon (C), boron (B), nitrogen (N), and silicon (Si), wherein the layer is formed on a dielectric material of the substrate. The at least one non-metal is delivered via a precursor gas, the precursor gas comprising one or more of C₂H₂, C₃H₆, B₂H₆, N₂, NH₃, and SiH₄.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Embodiments of the present disclosure generally relate to substrates for electronic devices and to methods of forming substrates. Substrates described herein can have superior device performance relative to conventional technologies. Methods described herein are reproducible and can yield uniform passivation layers. Further, embodiments described herein can enable, for example, streamlined material handling and integration and longer shelf life for the passivated substrates (passivated film rolls) than conventional technologies.

As is apparent from the foregoing general description and the specific aspects, while forms of the aspects have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, process operation, process operations, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, process operation, process operations, element, or elements and vice versa, such as the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. For example, the recitation of the numerical range 1 to 5 includes the subranges 1 to 4, 1.5 to 4.5, 1 to 2, among other subranges. As another example, the recitation of the numerical ranges 1 to 5, such as 2 to 4, includes the subranges 1 to 4 and 2 to 5, among other subranges. Additionally, within a range includes every point or individual value between its end points even though not explicitly recited. For example, the recitation of the numerical range 1 to 5 includes the numbers 1, 1.5, 2, 2.75, 3, 3.80, 4, 5, among other numbers. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “a layer” includes aspects comprising one, two, or more layers, unless specified to the contrary or the context clearly indicates only one layer is included.

While the foregoing is directed to aspects of the present disclosure, other and further aspects of the disclosure may be devised without departing from the basic scope thereof, and the scope thereof is determined by the claims that follow.

What is claimed is:

1. A method of forming a multi-metal hardmask film on a substrate disposed in a processing chamber, comprising:
flowing at least one pretreatment gas into the processing chamber; and
flowing a main deposition gas mixture into the processing chamber to form the multi-metal hardmask film, wherein the multi-metal hardmask film comprises a plurality of metals.

2. The method of claim 1, wherein the at least one pretreatment gas comprises one or more of a hydrogen containing gas and a nitrogen containing gas.

3. The method of claim 1, wherein the multi-metal hardmask film further comprises at least one non-metal.

4. The method of claim 3, wherein the at least one non-metal comprises one or more of carbon (C), boron (B), nitrogen (N), and silicon (Si).

5. The method of claim 1, wherein the plurality of metals comprise transition metals.

6. The method of claim 5, wherein the transition metals are selected from: tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr).

7. The method of claim 6, wherein the main deposition gas mixture comprises a plurality of metal containing precursors.

8. The method of claim 7, wherein the main deposition gas mixture further comprises at least one non-metal containing precursor, the at least one non-metal containing precursor comprising one or more of carbon (C), boron (B), nitrogen (N), and silicon (Si).

9. The method of claim 7, wherein at least one metal containing precursor of the plurality of metal containing precursors includes a halide precursor.

10. The method of claim 7, wherein at least one metal containing precursor of the plurality of metal containing precursors includes a metal-organic precursor.

11. The method of claim 1, further comprising diluting the main deposition gas mixture using at least one carrier gas.

12. The method of claim 11, wherein the at least one carrier gas comprises one or more of argon (Ar) and/or helium (He).

13. A method of forming a multi-metal hardmask film on a substrate disposed in a processing chamber, comprising:
flowing at least one pretreatment gas into the processing chamber, wherein the pretreatment gas comprises one or more of a hydrogen containing gas and a nitrogen containing gas;
flowing a main deposition gas mixture into the processing chamber to form the multi-metal hardmask film, wherein the multi-metal hardmask film comprises a plurality of metals; and
supplying a radiofrequency (RF) power while flowing the at least one pretreatment gas and while forming the multi-metal hardmask film.

14. The method of claim 13, wherein the RF power comprises a high frequency RF power between 300 Watts and 3000 Watts.

15. The method of claim 13, wherein the plurality of metals comprises two or more of tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr).

16. The method of claim 13, wherein the multi-metal hardmask film further comprises at least one non-metal, the at least one non-metal comprising one or more of carbon (C), boron (B), nitrogen (N), and silicon (Si).

17. The method of claim 13, wherein a temperature of the processing chamber is between 25° C. and 600° C. when forming the multi-metal hardmask film on the substrate.

18. The method of claim 13, wherein a pressure within the processing chamber is between 0.1 Torr and 100 Torr when forming the multi-metal hardmask film on the substrate.

19. A hardmask layer disposed on a substrate, comprising:
two or more metals selected from: tungsten (W), molybdenum (Mo), chromium (Cr), cobalt (Co), tantalum (Ta), ruthenium (Ru), titanium (Ti), rhenium (Re), hafnium (Hf), vanadium (V), niobium (Nb), osmium (Os), manganese (Mn), iron (Fe), and zirconium (Zr); and
at least one non-metal comprising one or more of carbon (C), boron (B), nitrogen (N), and silicon (Si),
wherein the layer is formed on a dielectric material of the substrate.

20. The hardmask layer of claim 19, wherein the layer disposed on the substrate has a grain size less than 35 Å.
